(19) United States
(12) Patent Application Publication
(10) Pub. No.: US 2026/0173952 A1
(43) Pub. Date: Jun. 18, 2026

(54) SEMICONDUCTOR PACKAGE AND FORMATION METHOD THEREOF

(71) Applicant: Taiwan Semiconductor Manufacturing Company, Ltd., Hsinchu (TW)

(72) Inventors: Jyun-Yang Wang, Hsinchu City (TW); Hsu-Hsien Chen, Hsinchu City (TW); Chen-Shien CHEN, Hsinchu County (TW); Yinlung Lu, Hsinchu (TW); Yao-Chun Chuang, Hsinchu City (TW); Tien-Chung Yang, Hsinchu City (TW); Wei-Hao Chen, New Taipei City (TW)

(73) Assignee: Taiwan Semiconductor Manufacturing Company, Ltd., Hsinchu (TW)

(21) Appl. No.: 18/979,396

(22) Filed: Dec. 12, 2024

(51) Int. Cl. H01L 23/31; H01L 21/56; H01L 21/78; H01L 23/00; H01L 25/07

(52) U.S. Cl. CPC H10W 74/134; H10W 74/014; H10W 74/147; H10W 90/00; H10P 54/00; H10W 90/792

(57) ABSTRACT

A semiconductor package and a formation method thereof are provided. The semiconductor package includes: a first device die; a second device die, stacked on and bonded to the first device die; and a gap fill dielectric, laterally surrounding the second device die, and locally recessed toward the second device die with respect to the first device die, such that lateral recesses are defined at outer sidewalls of the gap fill dielectric.

### BACKGROUND

Semiconductor industry has strived to continually reduce feature size and power consumption of various electronic components, while on the other hand increasing device density, wire density and operation frequency of the electronic components. These advanced electronic components also require smaller packages that utilize less area than packages of the past.

Three-dimensional integrated circuit (3DIC) is a recent development in semiconductor packaging in which multiple electronic components are stacked upon one another. 3DIC provides improved integration density and other advantages, such as greater operation speed and higher bandwidth, because of the decreased length of interconnects between the stacked dies. However, there are quite a few challenges to be overcome for the technology of 3DICs. As an example, while using laser grooving for singulating a top tier of an 3DIC, there is a risk that the incident energy penetrates through the top tier and reaches into a lower tier of the 3DIC, and damages the lower tier of the 3DIC.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view illustrating an intermediate structure of a semiconductor package, according to some embodiments of the present disclosure.

FIG. 1B is a schematic plan view illustrating configuration of device dies, a gap fill dielectric and dummy dies in the semiconductor package as shown in FIG. 1A, according to some embodiments of the present disclosure.

FIG. 1C is a schematic cross-sectional view illustrating a semiconductor package singulated from the semiconductor package as shown in FIG. 1A, according to some embodiments of the present disclosure.

FIG. 2 is a flow diagram illustrating a manufacturing process of the semiconductor package shown in FIG. 1C, according to some embodiments of the present disclosure.

FIG. 3A through FIG. 3G are schematic cross-sectional views illustrating intermediate structures at a series of stages during the manufacturing process as shown in FIG. 2.

FIG. 4A and FIG. 4B are respectively a schematic plan view illustrating configuration of device dies, gap fill dielectric and dummy dies in a semiconductor package, according to some embodiments of the present disclosure.

FIG. 5A is a schematic cross-sectional view illustrating an intermediate structure of a semiconductor package, according to some embodiments of the present disclosure.

FIG. 5B is a schematic plan view illustrating configuration of device dies, the gap fill dielectric and air gaps in the semiconductor package as shown in FIG. 5A, according to some embodiments of the present disclosure.

FIG. 5C is a schematic cross-sectional view illustrating a semiconductor package singulated from the semiconductor package as shown in FIG. 5A, according to some embodiments of the present disclosure.

FIG. 6A and FIG. 6B are respectively a schematic plan view illustrating configuration of device dies, gap fill dielectric and air gaps in a semiconductor package, according to some embodiments of the present disclosure.

FIG. 7A is a schematic cross-sectional view illustrating an intermediate structure of a semiconductor package, according to some embodiments of the present disclosure.

FIG. 7B is a schematic plan view illustrating configuration of device dies and surrounding vacancy in the semiconductor package as shown in FIG. 7A, according to some embodiments of the present disclosure.

FIG. 7C is a schematic cross-sectional view illustrating a semiconductor package singulated from the semiconductor package as shown in FIG. 7A, according to some embodiments of the present disclosure.

FIG. 8A is a schematic cross-sectional view illustrating an intermediate structure of a semiconductor package, according to some embodiments of the present disclosure.

FIG. 8B is a schematic plan view illustrating configuration of device dies and surrounding substance in the semiconductor package as shown in FIG. 8A, according to some embodiments of the present disclosure.

FIG. 8C is a schematic cross-sectional view illustrating a semiconductor package singulated from the semiconductor package as shown in FIG. 8A, according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a solution for ensuring that a lower tier of a three-dimensional semiconductor package would not be damaged due to singulation of a top tier of the three-dimensional semiconductor package.

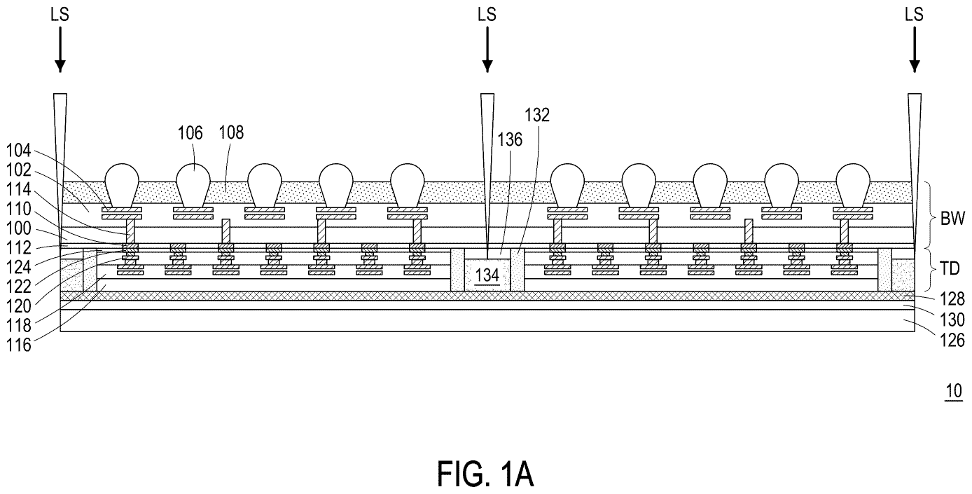

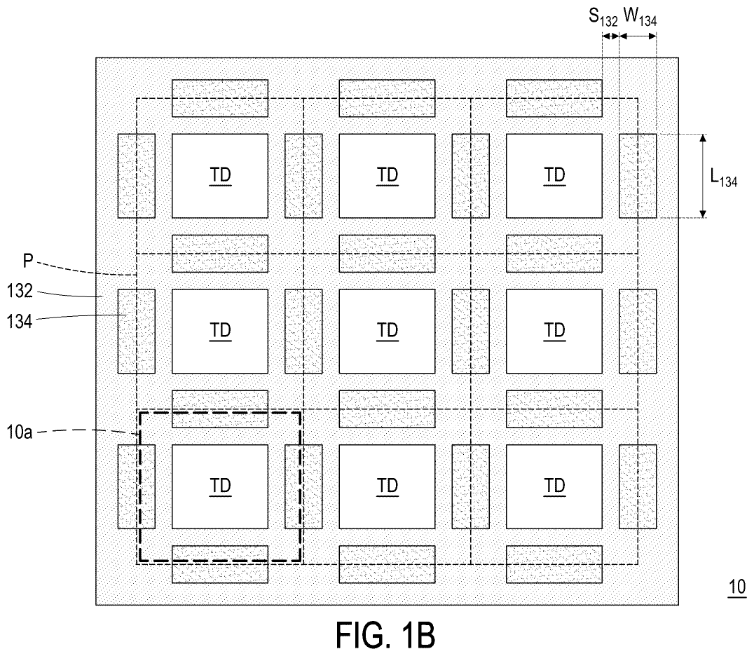

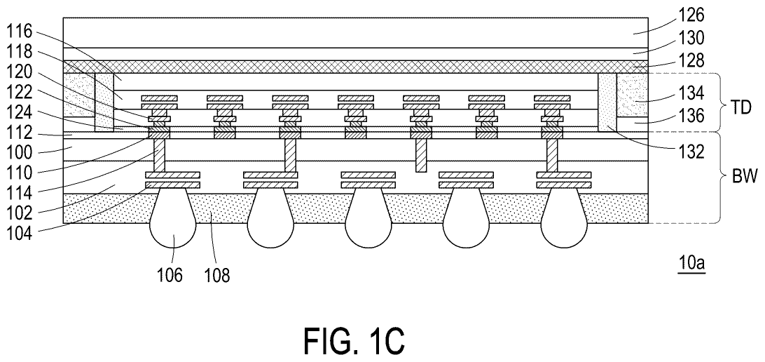

FIG. 1A is a schematic cross-sectional view illustrating an intermediate structure of a semiconductor package (referred to as a semiconductor package 10), according to some embodiments of the present disclosure.

The semiconductor package 10 includes a device wafer BW and multiple device dies TD bonded to the device wafer BW. As a result of the bonding, the device dies TD are stacked with the device wafer BW. At a certain stage as shown in FIG. 1A, the device wafer BW stacks on top of the device dies TD and defines a first tier of the semiconductor package 10, while the device dies TD define a second tier of the semiconductor package 10.

The device wafer BW includes a semiconductor substrate 100. Although not shown, active devices are formed on the semiconductor substrate 100, and a side of the semiconductor substrate 100 at which the active devices being deployed is referred to as an active side of the semiconductor substrate 100. A stack of metallization layers 102 are disposed on the active side of the semiconductor substrate 100, and conductive features 104 spreading in the metallization layers 102 interconnect the active devices to form an integrated circuit and rout the integrated circuit to an active side of the device wafer BW, which is a top side of the device wafer BW at the stage shown in FIG. 1A. An array of electrical connectors 106 are arranged at the active side of the device wafer BW, and may be laterally surrounded by one or more passivation layer(s) 108.

In some embodiments, the device wafer BW is attached to the device dies TD by its back side, which is defined by bonding pads 110 and a surrounding insulating layer 112 formed at a back side of the semiconductor substrate 100 that is facing away from the metallization layers 102. In these embodiments, at least some of the bonding pads 110 may be connected to the conductive features 104 in the metallization layers 102 via through substrate vias 114. The through substrate vias 114 are formed through the semiconductor substrate 100 from the back side of the semiconductor substrate 100. In some embodiments, the through substrate vias 114 further extend into the metallization layers 102.

As similar to the device wafer BW at the first tier, each of the device dies TD at the second tier may include a semiconductor substrate 116 with active devices (not shown) formed on its active side. In addition, a stack of metallization layers 118 are disposed on the active side of the semiconductor substrate 116, and conductive features 120 in the metallization layers 118 interconnect the active devices to form an integrated circuit and rout the integrated circuit to an active side of the device die TD, where bonding pads 122 and a surrounding insulating layer 124 are formed. In some embodiments, each of the device dies TD is bonded to the device wafer BW by its active side. In these embodiments, the bonding pads 122 at the active side of each device die TD may be bonded to the bonding pads 110 at the back side of the device wafer BW, and the insulating layer 124 at the active side of each device die TD may be bonded to the insulating layer 112 at the back side of the device wafer BW.

As the device wafer BW and the device dies TD are significantly thinned, a support substrate 126 may be attached to the bonded device wafer BW and the device dies TD to provide mechanical support for the semiconductor package 10. Specifically, the support substrate 126 is attached to the back sides of the device dies TD. In some embodiments, a bonding film 128 formed along back sides of the device dies TD is bonded with a bonding film 130 formed along a surface of the support substrate 126, to realize the attachment of the device wafer BW and the device dies TD. As an example, the bonding film 128 may be formed of SiN, SiON, SiCN, the like or combinations thereof, whereas the bonding film 130 may include a silicon oxide sub-layer, a silicon oxynitride sub-layer or a combination thereof. Although not shown, the bonding film 130 may be embedded with alignment marks, for facilitating accurate positioning of the device dies TD.

The device dies TD are laterally separated from one another, and a gap fill dielectric 132 is filled in between the device dies TD, and laterally encapsulating each of the device dies TD. In this way, a front surface of the gap fill dielectric 132 substantially coplanar with the active sides of the device dies TD (i.e., a top surface of the gap fill dielectric 132 as shown in FIG. 1A) is also bonded to the insulating layer 112 at the back side of the device wafer BW. On the other hand, a back surface of the gap fill dielectric 132 substantially coplanar with the back sides of the device dies TD (i.e., a bottom surface of the gap fill dielectric 132 as shown in FIG. 1A) is also covered by the bonding film 128, and is attached to the support substrate 126 through the bonding films 128, 130.

A dielectric material for forming the gap fill dielectric 132 is carefully selected, such that a mismatch of coefficient of thermal expansion (CTE) between the gap fill dielectric 132 and the device dies TD can be minimized. In some embodiments, the gap fill dielectric 132 is formed of silicon oxide. Despite that the CTE mismatch between the gap fill dielectric 132 and the device dies TD can be reduced, the gap fill dielectric 132 may not absorb ultraviolet (UV) light beams LS used for laser grooving operation during singulation of the semiconductor package 10. By describing that the gap fill dielectric 132 may/does not absorb the UV light beams LS, it covers that a small portion of the UV light beams LS could be absorbed while passing through the gap fill dielectric 132. In contrast, by describing that a component is capable of absorbing the UV light beams LS, it should be understood that UV absorption ability of such component is higher than UV absorption ability of the gap fill dielectric 132.

Specifically, during the laser grooving operation, the UV light beams LS may cut through the passivation layer(s) 108 and the metallization layers 102 of the device wafer BW, and stop on the active side of the semiconductor substrate 100 in the device wafer BW. Accidentally, the UV light beams LS does not stop on the active side of the semiconductor substrate 100, but further cut through the semiconductor substrate 100, and the gap fill dielectric 132 may be exposed to the UV light beams LS. Since the gap fill dielectric 132 does not absorb UV light, the UV light beams LS may penetrate through the gap fill dielectric 132 to reach the bonding film 128, which may have higher UV absorption ability than the gap fill dielectric 132. As a consequence, delamination at an interface between the bonding film 128 and the gap fill dielectric 132 may result in crack in the gap fill dielectric 132. During a subsequent reliability test, such crack may further propagate into the device dies TD, and damage reliability of the device dies TD.

As a solution, in some embodiments, dummy dies 134 are placed in the gap fill dielectric 132, and positioned on the paths of the UV light beams LS. The dummy dies 134 are capable of absorbing UV light, thus can prevent the UV light beams LS from reaching to the bonding film 128. In this way, delamination between the bonding film 128 and the gap fill dielectric 132 can be effectively avoided, and crack(s) can be avoided from forming in the gap fill dielectric 132 along the interface of the bonding film 128 and the gap fill dielectric 132. Accordingly, the reliability of the device dies TD may not be compromised.

Specifically, the dummy dies 134 may respectively include a semiconductor substrate, which may not be formed with any electronic component. In addition, the dummy dies 134 are each laterally surrounded by the gap fill dielectric 132, and are in lateral contact with the device dies TD through the gap fill dielectric 132. In some embodiments, back sides of the dummy dies 134 are substantially coplanar with the back surface of the gap fill dielectric 132. Further, in some embodiments, front sides of the dummy dies 134 are respectively bonded to the insulating layer 112 at the back side of the device wafer BW through a bonding layer 136. Front surfaces of the bonding layers 136 may be substantially coplanar with the front surface of the gap fill dielectric 132 and the active sides of the device dies TD. As an example, the dummy dies 134 may respectively include a silicon substrate without any electrical component, while the bonding layer 136 may be formed of silicon oxide or any suitable insulating material. In some embodiments, a thickness of each dummy die 134 ranges from about 30 μm to about 775 μm, whereas a thickness of each bonding layer 136 is no more than 10 μm.

FIG. 1B is a schematic plan view illustrating configuration of the device dies TD, the gap fill dielectric 132 and the dummy dies 134 in the semiconductor package 10, according to some embodiments of the present disclosure.

As shown in FIG. 1B, the gap fill dielectric 132 extends in between the device dies TD and laterally encapsulates each of the device dies TD. In addition, the dummy dies 134 are placed in the gap fill dielectric 132, and positioned on paths P of the UV light beams LS, to prevent the afore-mentioned cracks from forming around and further extending into the device dies TD. According to some embodiments, the dummy dies 134 are separately arranged, and each extend in between adjacent ones of the device dies TD. As an example, when the device dies TD are respectively rectangular, four of the dummy dies 134 are placed along four lateral sides of each device die TD, and are separated from one another at four die corners.

A width W₁₃₄ of each dummy die 134 is shorter than a spacing between adjacent ones of the device dies TD, while a length L₁₃₄ of each dummy die 134 is substantially equal to or greater than a side length of each device die TD. In some embodiments, the width W₁₃₄ is about 240 μm, and a spacing S₁₃₂ between each dummy die 134 and an adjacent device die TD may depend on die-to-die spacing and the width W₁₃₄. In addition, as an example, the length L₁₃₄ may be substantially identical with the side length of each device die TD, and may range from 1 mm to 32 mm.

FIG. 1C is a schematic cross-sectional view illustrating a semiconductor package 10a singulated from the semiconductor package 10, according to some embodiments of the present disclosure.

After performing the laser grooving for cutting through the first tier of the semiconductor package 10 (defined by the device wafer BW), a mechanical sawing operation may be performed along the same paths of the laser grooving (i.e., the paths P as indicated in FIG. 1B), to cut through the remaining structure. That is, during the mechanical sawing operation, the second tier of the semiconductor package 10 (defined by the device dies TD, the gap fill dielectric 132 and the dummy dies 134) as well as the support substrate 126 lying below are cut into separated pieces. Also, the bonding layers 136 covering the dummy dies 134 and the bonding films 128, 130 covering the support substrate 126 are cut along with the gap fill dielectric 132, the dummy dies 134 and the support substrate 126.

One of the resulted structures is schematically depicted in FIG. 1C, as the semiconductor package 10a. Since the dummy dies 134 are cut through during the singulation performed by a combination of the laser grooving and mechanical sawing operations, sliced dummy dies 134 may expose at sidewalls of the singulated semiconductor packages (including the semiconductor package 10a). According to some embodiments, for each of the singulated semiconductor packages, sidewalls of the dummy dies 134 are substantially coplanar with sidewalls of the overlying bonding layers 136 and the singulated device wafer BW (or referred to as a first device die, whereas the device die TD is also referred to as a second device die), as well as sidewalls of the underlying bonding films 128, 130 and the support substrate 126.

As shown in FIG. 1B, the paths P for both of the laser grooving and the mechanical sawing not only extend through the dummy dies 134, but also extend through the gap fill dielectric 132. In this way, the gap fill dielectric 132 may also expose at the sidewalls of the singulated semiconductor packages (including the semiconductor package 10a as shown in FIG. 1C). In some embodiments, for each of the singulated semiconductor packages, sidewalls of the gap fill dielectric 132 are substantially coplanar with the sidewalls of the dummy dies 134, the sidewalls of the bonding layers 136, the sidewalls of the singulated device wafer BW (i.e., the second device die), the sidewalls of the bonding films 128, 130 and the sidewalls of the support substrate 126. Further, the gap fill dielectric 132 can be described as being locally recessed toward the device die TD (i.e., the first device die) with respect to the singulated device wafer BW (i.e., the second device die) and the support substrate 126, and the dummy dies 134 as well as the bonding layers 136 are filled in the resulted lateral recesses.

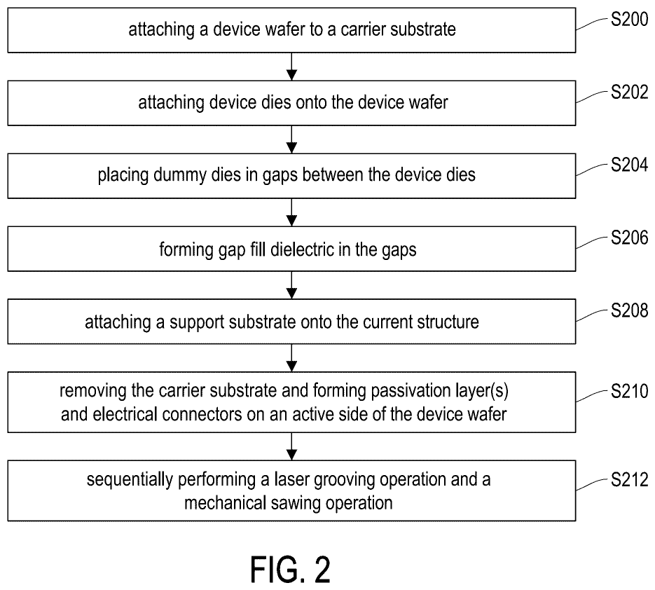

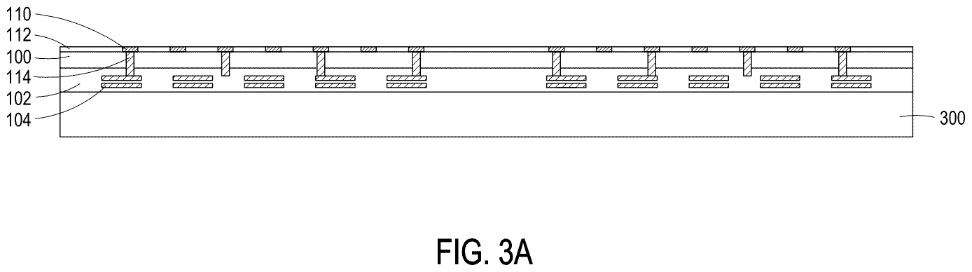

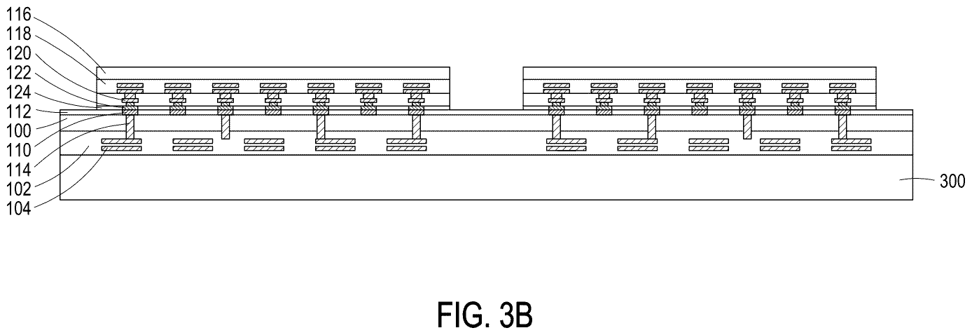

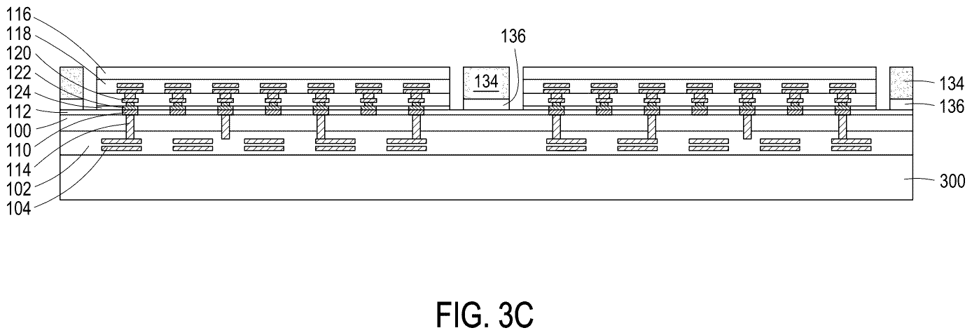

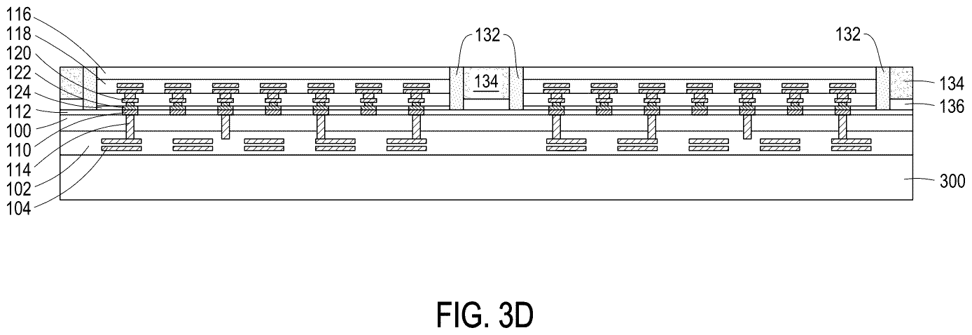

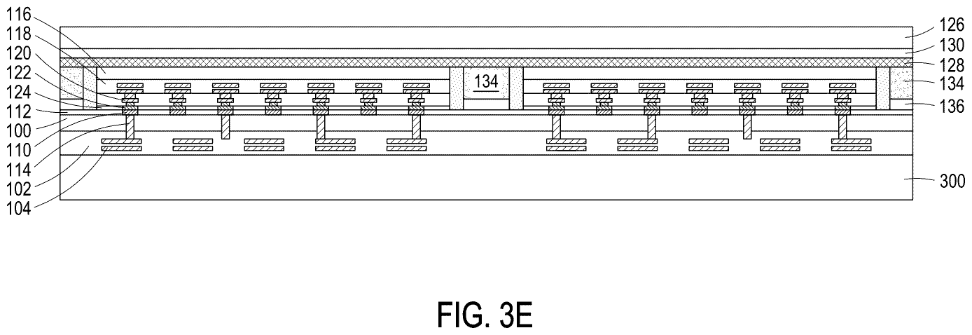

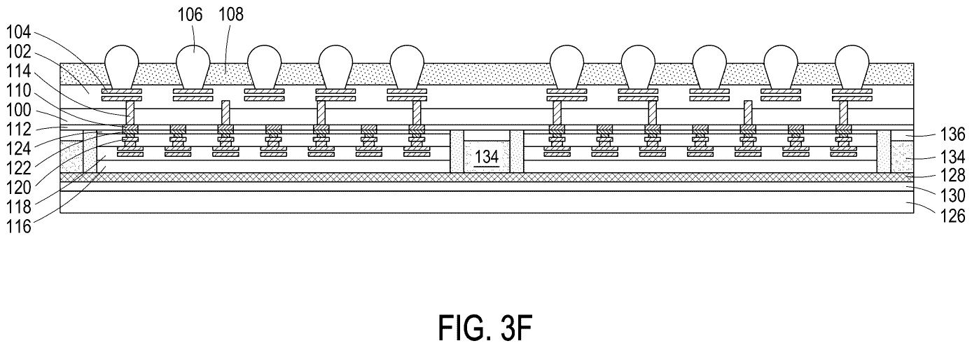

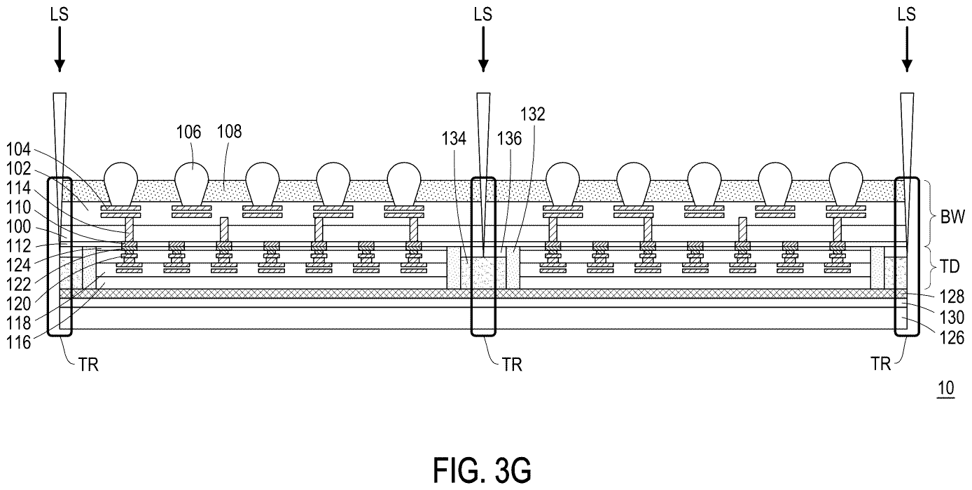

FIG. 2 is a flow diagram illustrating a manufacturing process of the semiconductor package 10a, according to some embodiments of the present disclosure. FIG. 3A through FIG. 3G are schematic cross-sectional views illustrating intermediate structures at a series of stages during the manufacturing process as shown in FIG. 2.

Referring to FIG. 2 and FIG. 3A, an operation S200 is performed, and the device wafer BW is attached to a carrier substrate 300. At the present stage, the device wafer BW has not been formed with the passivation layer(s) 108 and the electrical connectors 106, and is attached to the carrier substrate 300 by its active side, which is now defined by an outermost one of the metallization layers 102. Upon attachment, a bonding side of the device wafer BW, which is defined by the bonding pads 110 and the insulating layer 112, is exposed for receipting the device dies TD.

Referring to FIG. 2 and FIG. 3B, an operation S202 is performed, and the device dies TD are attached onto the device wafer BW. In some embodiments, the insulating layers 124 and the bonding pads 122 defining bonding sides of the device dies TD are attached to the insulating layer 112 and the bonding pads 110 defining the bonding side of the device wafer BW. Specifically, in these embodiments, the insulating layers 124 are respectively bonded to the insulating layer 112, whereas the bonding pads 122 are respectively bonded to one of the bonding pads 110. The attached device dies TD are laterally separated from one another, and gaps GP are defined in between and surrounding the device dies TD.

Referring to FIG. 2 and FIG. 3C, an operation S204 is performed, and the dummy dies 134 are placed in the gaps GP. Specifically, as described, the dummy dies 134 are placed on the paths of the subsequently performed laser grooving and mechanical sawing. In some embodiments, the dummy dies 134 are attached to the insulating layer 112 of the device wafer BW through the bonding layers 136.

Referring to FIG. 2 and FIG. 3D, an operation S206 is performed, and the gap fill dielectric 132 is formed to fill up the gaps GP. Specifically, formation of the gap fill dielectric 132 may involve a deposition process, such as a chemical vapor deposition (CVD) process. Initially, the gap fill dielectric 132 may be formed to a height over top sides of the dummy dies 134 and the device dies TD, and may be etched back to expose the top sides of the dummy dies 134 and the device dies TD.

Referring to FIG. 2 and FIG. 3E, an operation S208 is performed, and the support substrate 126 is attached onto the current structure. In some embodiments, the support substrate 126 is attached to the device dies TD, the gap fill dielectric 132 and the dummy dies 134 through the bonding films 128, 130. In these embodiments, the bonding film 128 may be formed (e.g., deposited) on the device dies TD, the gap fill dielectric 132 and the dummy dies 134, whereas the bonding film 130 may be formed on the support substrate 126. Upon formation of the bonding films 128, 130, the support substrate 126 is attached to the device dies TD, the gap fill dielectric 132 and the dummy dies 134 by bonding the bonding films 128, 130 with each other.

Referring to FIG. 2 and FIG. 3F, at a step S210, the carrier substrate 300 is removed and the passivation layer(s) 108 as well as the electrical connectors 106 are formed on the active side of the device wafer BW. Specifically, prior to the removal of the carrier substrate 300, the entire structure may be flipped over, such that the support substrate 126 is holding the entire structure from below and the carrier substrate 300 is exposed. Upon removal of the carrier substrate 300, the outermost metallization layer 102 may be exposed, and the passivation layer(s) 108 as well as the electrical connectors 106 are formed thereon. The resulted structure is the semiconductor package 10 as described with reference to FIG. 1A.

Referring to FIG. 2 and FIG. 3G, at a step S212, the laser grooving operation and the mechanical sawing operation are sequentially performed. As described, the laser grooving operation utilizes the UV light beams LS to cut into the device wafer BW along the paths P as shown in FIG. 1B. Normally, the laser grooving operation stops while the semiconductor substrate 100 of the device wafer BW is exposed. Even if the UV light beans LS accidentally cut through the semiconductor substrate 100, the underlying dummy dies 134 may absorb the UV light, to prevent the UV light beams LS from reaching to the bonding film 128 below the dummy dies 134. Therefore, formation of cracks along the interface between the bonding film 128 and the gap fill dielectric 132 can be effectively avoided, and promising reliability of the device dies TD can be ensured. Following the laser grooving operation, the mechanical sawing operation is performed along the same paths of the laser grooving operation (i.e., the paths P as shown in FIG. 1B), to form trenches TR penetrating through the bonding layers 136, the dummy dies 134, the gap fill dielectric 132, the bonding films 128, 130 and the support substrate 126. As a result, the semiconductor package 10 is singulated into multiple pieces including the semiconductor package 10a as described with reference to FIG. 1C.

In the embodiments described with reference to FIG. 1B, a single one of the dummy dies 134 is placed in between adjacent device dies TD, and extends along opposing sides of these adjacent device dies TD. However, the present disclosure is not limited to this configuration.

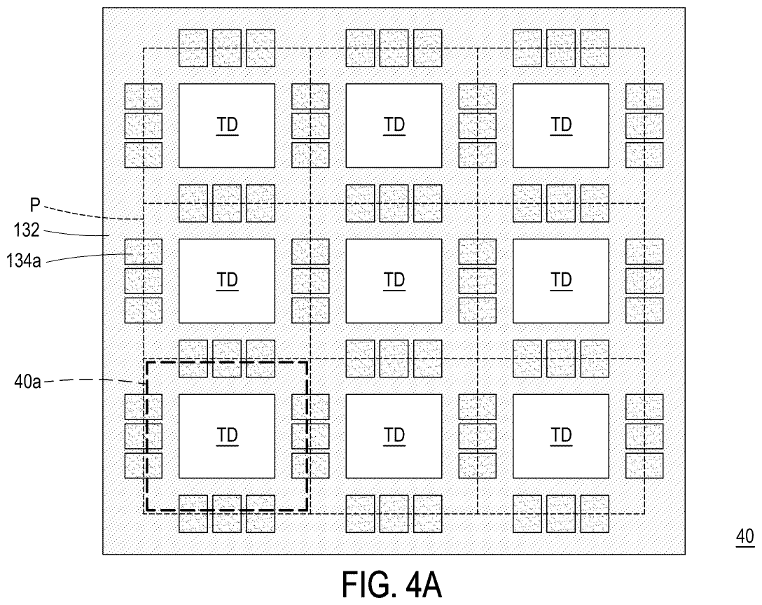

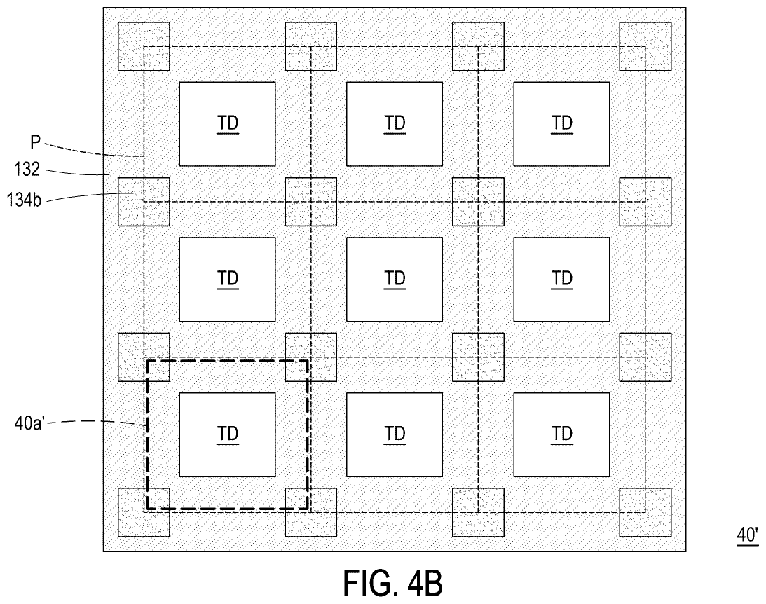

FIG. 4A and FIG. 4B are schematic plan views illustrating configurations of the device dies TD, the gap fill dielectric 132 and dummy dies 134a/134b placed in the gap fill dielectric 132, in semiconductor packages 40, 40′ according to some embodiments of the present disclosure.

The semiconductor package 40 shown in FIG. 4A is similar to the semiconductor package 10 as described with reference to FIG. 1A and FIG. 1B, except that the semiconductor package 40 includes the dummy dies 134a spreading in the gap fill dielectric 132, rather than the dummy dies 134. As shown in FIG. 4A, the dummy dies 134a are arranged along the paths P of the laser grooving and the mechanical sawing, and each device die TD is spaced apart from an adjacent device die TD with a group of the dummy dies 134a arranged in between. In the example that each device die TD has a rectangular plan view, each device die TD may be laterally surrounded by four groups of the dummy dies 134a.

The dummy dies 134a in each group may be arranged along opposing sides of the device dies TD at opposite sides, but may not be arranged beyond the side length of the adjacent device dies TD. Further, the dummy dies 134a in each group are laterally separated from one another, and a spacing between the dummy dies 134a in each group may be dependent on dimensions of the dummy dies 134, dimensions of the device dies TD and an amount of the dummy dies 134a in each group. As compared to the dummy dies 134 described with reference to FIG. 1A to FIG. 1C, the dummy dies 134a as shown in FIG. 4A may be smaller in size. Owing to the compactness, the dummy dies 134a may be less susceptible to warpage.

Although not shown, the dummy dies 134a may be respectively in contact with the device wafer BW through one of the bonding layers 136, and are each attached to the support substrate 126 through the bonding films 128, 130 in between, as similar to the dummy dies 134 described with reference to FIG. 1A. Also, upon singulation, the dummy dies 134a are exposed at sidewalls of the singulated semiconductor packages (including a semiconductor package 40a), and sidewalls of the dummy dies 134a may be substantially coplanar with rest portions of the sidewalls of the singulated semiconductor packages, as similar to the singulated dummy dies 134 described with reference to FIG. 1C.

The semiconductor package 40′ shown in FIG. 4B is also similar to the semiconductor package 10 described with reference to FIG. 1A and FIG. 1B, except that the semiconductor package 40′ includes the dummy dies 134b spreading in the gap fill dielectric 132, rather than the dummy dies 134. As shown in FIG. 4B, the dummy dies 134b are positioned at intersections of the paths P along which the laser grooving and mechanical sawing are performed. Corners of the device dies TD are close to these intersections, and are each subjected to twice of the laser grooving and twice of the mechanical sawing. Therefore, the corners of the device dies TD are particularly susceptible for reliability issue caused by formation of cracks in the gap fill dielectric 132 during the laser grooving. As similar to the effect of disposing the dummy dies 134 described with reference to FIG. 1A and FIG. 1B, placing the dummy dies 134b in the gap fill dielectric 132 can absorb the UV light beams LS accidentally cutting through the device wafer BW during the laser grooving, thus prevent formation of the cracks. As a difference from the dummy dies 134, the dummy dies 134b focus on protecting the corners of the device dies TD that are most susceptible for reliability issue.

Although not shown, the dummy dies 134b may be respectively in contact with the device wafer BW through one of the bonding layers 136, and are each attached to the support substrate 126 through the bonding films 128, 130 in between, as similar to the dummy dies 134 described with reference to FIG. 1A. Also, upon singulation, the dummy dies 134b are exposed at sidewalls of the singulated semiconductor packages (including a semiconductor package 40a′), and sidewalls of the dummy dies 134b may be substantially coplanar with rest portions of the sidewalls of the singulated semiconductor packages, as similar to the singulated dummy dies 134 described with reference to FIG. 1C.

As described, the dummy dies 134/134a/134b are used for absorbing UV light and thus preventing formation of cracks in the gap fill dielectric 132. In alternative embodiments, other mechanisms are used for preventing formation of the cracks.

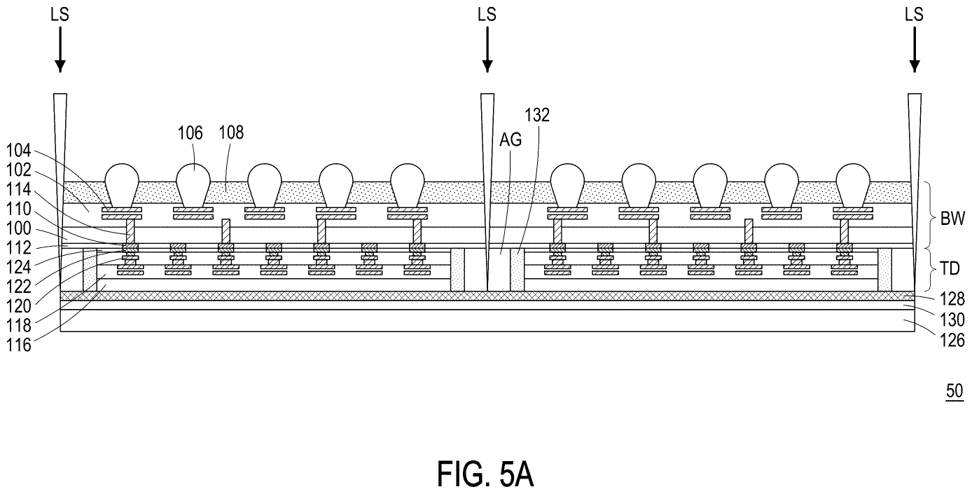

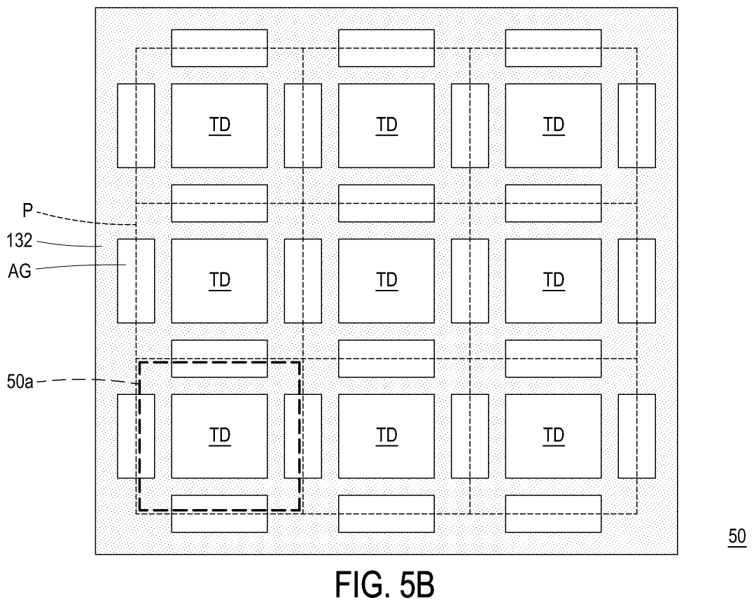

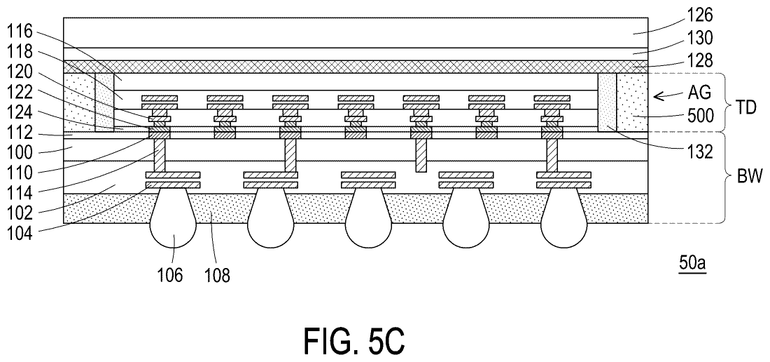

FIG. 5A is a schematic cross-sectional view illustrating an intermediate structure of a semiconductor package (referred to as a semiconductor package 50), according to some embodiments of the present disclosure. FIG. 5B is a schematic plan view illustrating configuration of the device dies TD, the gap fill dielectric 132 and air gaps AG in the semiconductor package 50, according to some embodiments of the present disclosure.

The semiconductor package 50 is similar to the semiconductor package 10 described with reference to FIG. 1A, except including the airgaps AG in the gap fill dielectric 132, rather than the dummy dies 134. In addition, the bonding film 128 or the bonding film 130 may be omitted. Alternatively, none of the bonding films 128, 130 is omitted from the semiconductor package 50. As shown in FIG. 5A and FIG. 5B, the air gaps AG penetrating through the gap fill dielectric 132 are placed on the paths P of the UV light beams LS used for the laser grooving. If the UV light beams LS accidentally cut through the device wafer BW, portions of the bonding film 128/130 lying below the air gaps AG would be exposed to the UV light beams LS, and may be damaged accordingly. Nonetheless, since these portions of the bonding film 128/130 are not covered by the gap fill dielectric 132, cracks would not be formed in the gap fill dielectric 132 as a result of the damage of the bonding film 128. Therefore, reliability of the device dies TD may not be affected by exposing the bonding film 128/130 to the UV light beams LS.

According to some embodiments, arrangement of the air gaps AG in the gap fill dielectric 132 is identical with arrangement of the dummy dies 134 as described with reference to FIG. 1B. As shown in FIG. 5B, the air gaps AG are formed in the gap fill dielectric 132, and positioned on the paths P of the laser grooving and mechanical sawing operations, to prevent the afore-mentioned cracks from forming around and further extending into the device dies TD. According to some embodiments, the air gaps AG are separately arranged, and each extend in between adjacent ones of the device dies TD. As an example, when the device dies TD are respectively rectangular, four of the air gaps AG are placed along four lateral sides of each device die TD, and are separated from one another at four die corners.

In addition to being arranged in the same way as the dummy dies 134, the air gaps AG may be identical with the dummy dies 134 in terms of dimensional ranges and a range of the spacing to the device dies TD.

In regarding manufacturing, process for forming the semiconductor package 50 is similar to the process described with reference to FIG. 2 and FIG. 3A to FIG. 3G, except for a few differences. Specifically, disposing the dummy dies 134 before formation of the gap fill dielectric 132 is omitted. In addition, the gap fill dielectric 132 is patterned to form the air gaps AG. Further, the bonding films 128, 130 may be formed on the support substrate 126, then the support substrate 126 is attached to the device dies TD through the bonding films 128, 130. Alternatively, formation of the bonding film 128 or formation of the bonding film 130 may be omitted, and the bonding film 128 or the bonding film 130 formed on the support substrate 126 is attached to the device dies TD for implementing bonding between the support substrate 126 and the device dies TD.

In some embodiments, the gap fill dielectric 132 is deposited after bonding the device dies TD to the device wafer BW, then a lithography process as well as an etching process are performed to remove portions of the gap fill dielectric 132, for patterning the gap fill dielectric 132 and forming the air gaps AG in the gap fill dielectric 132. In alternative embodiments, masking patterns (e.g., photoresist patterns) are formed before deposition of the gap fill dielectric 132. After depositing the gap fill dielectric 132 around the masking patterns, the masking patterns are removed, so as to form the air gaps AG in the gap fill dielectric 132.

FIG. 5C is a schematic cross-sectional view illustrating a semiconductor package 50a singulated from the semiconductor package 50, according to some embodiments of the present disclosure.

After performing the laser grooving and the mechanical sawing along the paths P shown in FIG. 5B, structures including the semiconductor package 50a are singulated from the semiconductor package 50. Since the laser grooving and the mechanical sawing cut through the air gaps AG, the semiconductor package 50a is laterally recessed at locations of the air gaps AG. To be more specific, sidewalls of the gap fill dielectric 132 is locally dented at the locations of the air gaps AG. On the other hand, other portions of the sidewalls of the gap fill dielectric 132 may be substantially coplanar with sidewalls of the singulated device wafer BW (i.e., the second device die), sidewalls of the support substrate 126 as well as sidewalls of the bonding films 128, 130 (or sidewalls of the bonding film 128/130, if one of the bonding films 128, 130 is omitted).

During further packaging process, the lateral recesses resulted by the air gaps AG may be filled with an encapsulant 500. As an example, while the gap fill dielectric 132 is formed of silicon oxide, the encapsulant 500 may be provided by a molding compound, such as epoxy or the like.

It should be noted that the air gaps AG are not limited to the arrangement shown in FIG. 5B. The air gaps AG can have various arrangement, as long as they are formed on the paths P of the laser grooving.

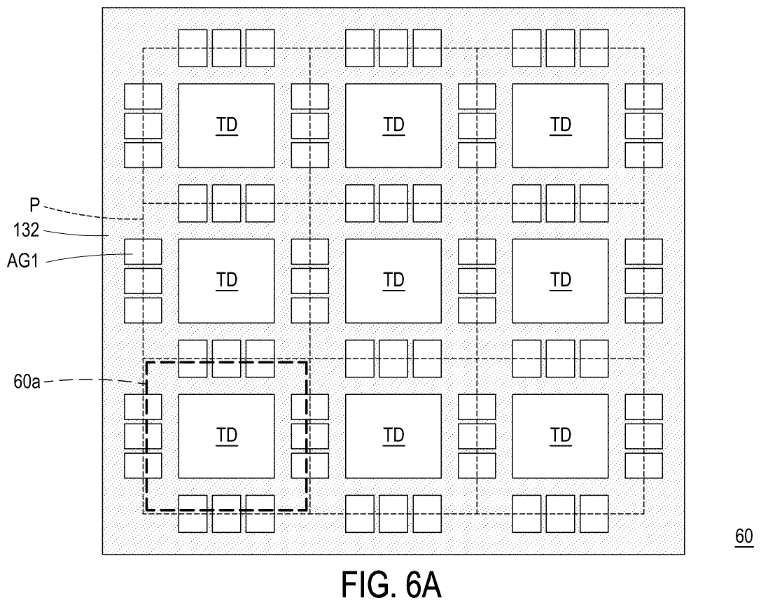

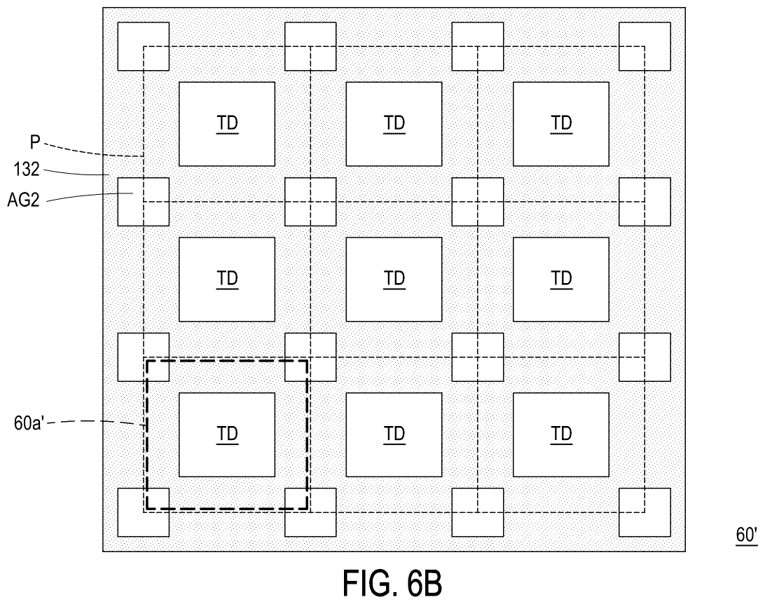

FIG. 6A and FIG. 6B are schematic plan views illustrating configurations of the device dies TD, the gap fill dielectric 132 and air gaps AG1/AG2 formed in the gap fill dielectric 132, in semiconductor packages 60, 60′ according to some embodiments of the present disclosure.

The semiconductor package 60 shown in FIG. 6A is similar to the semiconductor package 50 as described with reference to FIG. 5A and FIG. 5B, except that the air gaps AG1 in the semiconductor package 60 are arranged differently from the air gaps AG in the semiconductor package 50. Specifically, while the air gaps AG in the semiconductor package 50 are arranged according to the arrangement of the dummy dies 134 in the semiconductor package 10 as shown in FIG. 1B, the air gaps AG1 in the semiconductor package 60 are arranged identically as the dummy dies 134a in the semiconductor package 40 as described with reference to FIG. 4A. As shown in FIG. 6A, the air gaps AG1 are arranged along the paths P of the laser grooving and the mechanical sawing, and each device die TD is spaced apart from an adjacent device die TD with a group of the air gaps AG1 arranged in between. In the example that each device die TD has a rectangular plan view, each device die TD may be laterally surrounded by four groups of the air gaps AG1.

The air gaps AG1 in each group may be arranged along opposing sides of the device dies TD at opposite sides, but may not be arranged beyond the side length of the adjacent device dies TD. Further, the air gaps AG1 in each group are laterally separated from one another, and a spacing between the air gaps AG1 in each group may be dependent on dimensions of the air gaps AG1, dimensions of the device dies TD and an amount of the air gaps AG1 in each group. As compared to the air gaps AG described with reference to FIG. 5A to FIG. 5C, the air gaps AG1 as shown in FIG. 6A may be smaller in size. Nonetheless, the process for forming the air gaps AG in the semiconductor package 50 may be used for forming the air gaps AG1 in the semiconductor package 60, except that the involved lithography process may be adjusted.

Although not shown, upon singulation, lateral recesses would appear on sidewalls of the singulated semiconductor packages. Specifically, in each of the singulated semiconductor packages (including a semiconductor package 60a), sidewalls of the gap fill dielectric 132 are locally dented at the locations of the air gaps AG1. On the other hand, other portions of the sidewalls of the gap fill dielectric 132 may be substantially coplanar with sidewalls of the device wafer BW, sidewalls of the support substrate 126 and sidewalls of the bonding films 128, 130 (or sidewalls of the bonding film 128/130, if one of the bonding films 128, 130 is omitted). During further packaging process, the lateral recesses resulted by the air gaps AG1 may be filled with another gap fill material, such as a molding compound formed of epoxy or the like.

The semiconductor package 60′ shown in FIG. 6B is also similar to the semiconductor package 50 described with reference to FIG. 5A and FIG. 5B, except that the air gaps AG2 in the semiconductor package 60′ are arranged differently from the air gaps AG in the semiconductor package 50. Specifically, while the air gaps AG in the semiconductor package 50 are arranged according to the arrangement of the dummy dies 134 in the semiconductor package 10 as shown in FIG. 1B, the air gaps AG2 in the semiconductor package 60′ are arranged identically as the dummy dies 134b in the semiconductor package 40′ described with reference to FIG. 4B. As shown in FIG. 6B, the air gaps AG2 are positioned at intersections of the paths P along which the laser grooving and mechanical sawing are performed, to particularly protect corners of the device dies TD that are susceptible for reliability issue caused by formation of cracks in the gap fill dielectric 132 during the laser grooving.

The process for forming the air gaps AG in the semiconductor package 50 may be used for forming the air gaps AG2 in the semiconductor package 60′, except that the involved lithography process may be adjusted. Although not shown, upon singulation, lateral recesses would appear on sidewalls of the singulated semiconductor packages (including a semiconductor package 60a′). Specifically, in each of the singulated semiconductor packages, sidewalls of the gap fill dielectric 132 are locally dented at the locations of the air gaps AG2. On the other hand, other portions of the sidewalls of the gap fill dielectric 132 may be substantially coplanar with sidewalls of the device wafer BW, sidewalls of the support substrate 126 and sidewalls of the bonding films 128, 130 (or sidewalls of the bonding film 128/130, if one of the bonding films 128, 130 is omitted). During further packaging process, the lateral recesses resulted by the air gaps AG2 may be filled with another gap fill material, such as a molding compound formed of epoxy or the like.

According to further embodiments, the entire gap fill dielectric 132 susceptible for formation of cracks is entirely omitted.

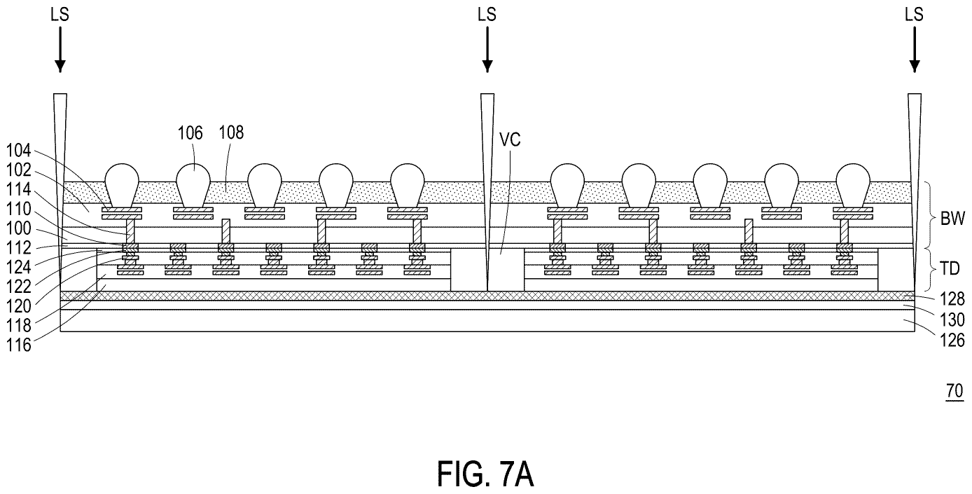

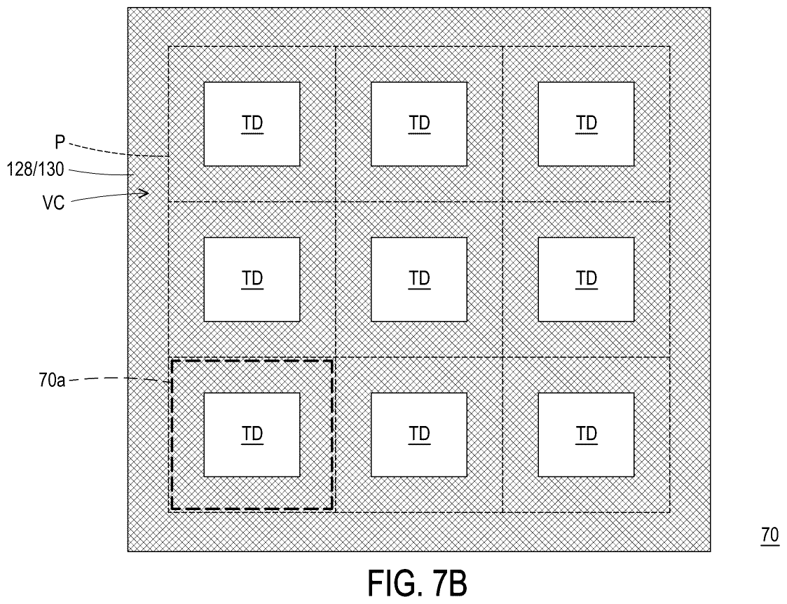

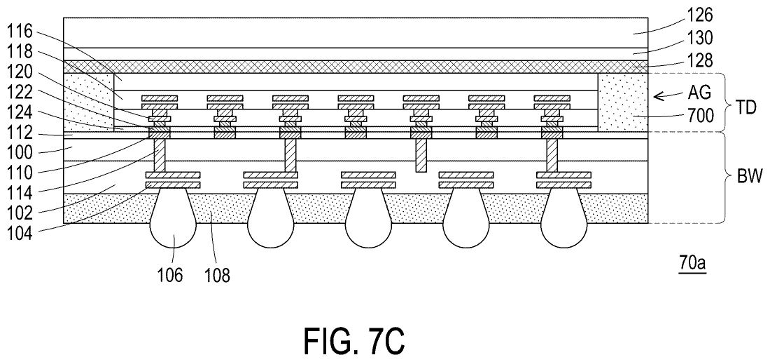

FIG. 7A is a schematic cross-sectional view illustrating an intermediate structure of a semiconductor package (referred to as a semiconductor package 70), according to some embodiments of the present disclosure. FIG. 7B is a schematic plan view illustrating configuration of the device dies TD and surrounding vacancy in the semiconductor package 70, according to some embodiments of the present disclosure.

The semiconductor package 70 is similar to the semiconductor package 10 described with reference to FIG. 1A, except that the dummy dies 134 as well as the gap fill dielectric 132 are absent in the semiconductor package 70. In addition, the bonding film 128 or the bonding film 130 may be omitted. Alternatively, none of the bonding films 128, 130 is omitted. As shown in FIG. 7A and FIG. 7B, owing to absence of the gap fill dielectric 132 and the dummy dies 134, a vacancy VC is defined around the device dies TD, and between the device wafer BW and the bonding film 128/130 at opposite sides of the device dies TD. In this way, the paths P of the laser grooving and the mechanical sawing overlap the vacancy VC. If the UV light beams LS accidentally cut through the device wafer BW during the laser grooving, portions of the bonding film 128/130 lying below the vacancy VC would expose to the UV light beams LS, and may be damaged accordingly. Nonetheless, since these portions of the bonding film 128/130 are not covered by any gap filling material at this stage, the damages of the bonding film 128/130 would not cause formation of cracks in a substance around the device dies TD. Therefore, reliability of the device dies TD may not be affected by exposing the bonding film 128/130 to the UV light beams LS.

In regarding manufacturing, process for forming the semiconductor package 70 is similar to the process described with reference to FIG. 2 and FIG. 3A to FIG. 3G, except for a few differences. Specifically, placing the dummy dies 134 and forming the gap fill dielectric 132 are omitted in the process for forming the semiconductor package 70. In addition, the bonding films 128, 130 may be formed on the support substrate 126, then the support substrate 126 is attached to the device dies TD through the bonding films 128, 130. Alternatively, formation of the bonding film 128 or formation of the bonding film 130 can be omitted, and the bonding film 128 or the bonding film 130 formed on the support substrate 126 may be attached to the device dies TD for implementing bonding between the support substrate 126 and the device dies TD.

FIG. 7C is a schematic cross-sectional view illustrating a semiconductor package 70a singulated from the semiconductor package 70, according to some embodiments of the present disclosure.

After performing the laser grooving and the mechanical sawing along the paths P shown in FIG. 7B, structures including the semiconductor package 70a are singulated from the semiconductor package 70. Since the laser grooving and the mechanical sawing cut through the vacancy VC around the device dies TD, the device dies TD are exposed at sidewalls of the singulated semiconductor packages upon singulation. Further, the sidewalls of the singulated semiconductor package are locally recessed into the device dies TD. To be more specific, in each of the singulated semiconductor packages (e.g., the semiconductor package 70a), sidewalls of the device die TD (also referred to as the second device die) are laterally recessed with respect to sidewalls of the singulated device wafer BW (also referred to as the first device die), sidewalls of the support substrate 126 and sidewalls of the bonding films 128 130 (or sidewalls of the bonding film 128/130 if one of the bonding films 128, 130 is omitted).

During further packaging process, the lateral recesses resulted by the vacancy VC may be filled with an encapsulant 700. As an example, the encapsulant 700 may be provided by a molding compound, such as epoxy or the like.

As described, formation of cracks in the gap fill dielectric 132 during the laser grooving can be realized by forming air gaps in the gap fill dielectric 132 along the paths P of the laser grooving or entirely omitting the gap fill dielectric 132. In further embodiments, formation of cracks around the device dies TD can also be prevented by filling the gaps around the device dies TD by using a substance capable of absorbing UV lights.

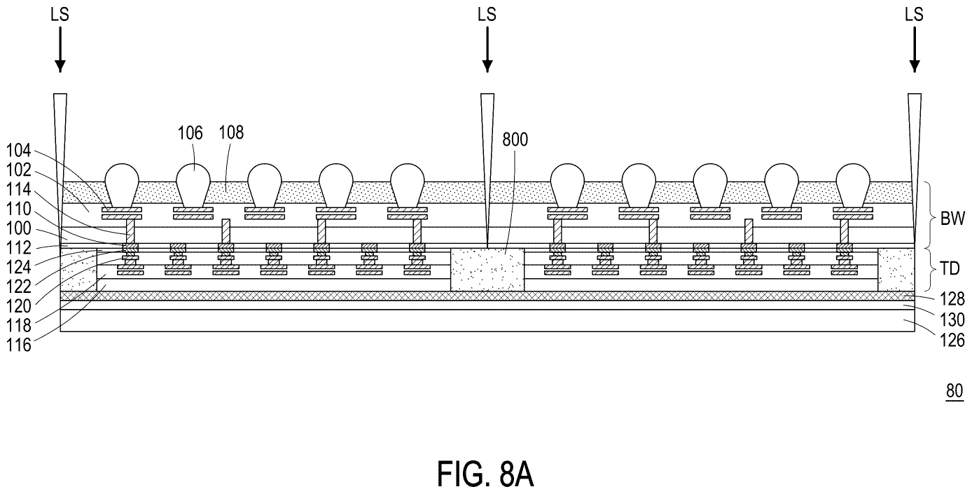

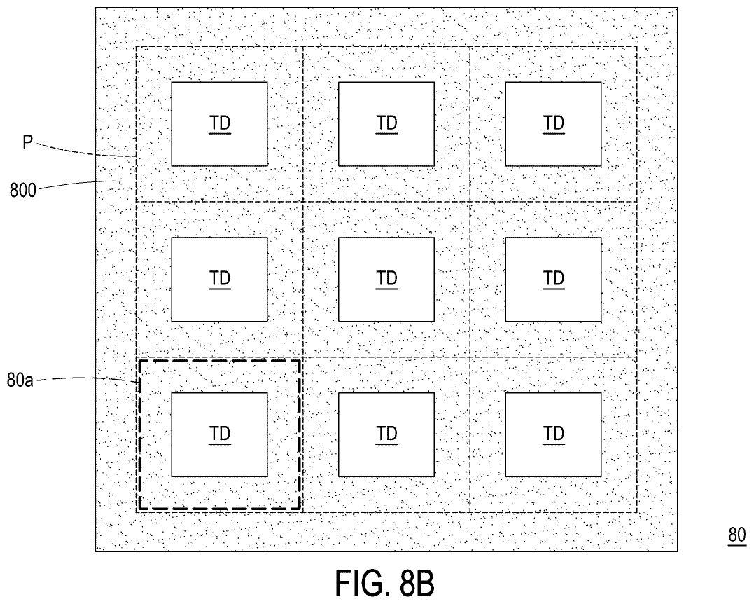

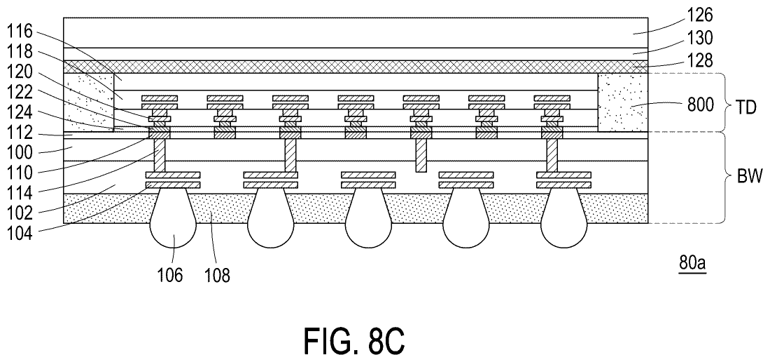

FIG. 8A is a schematic cross-sectional view illustrating an intermediate structure of a semiconductor package (referred to as a semiconductor package 80), according to some embodiments of the present disclosure. FIG. 8B is a schematic plan view illustrating configuration of the device dies TD and surrounding substance in the semiconductor package 80, according to some embodiments of the present disclosure.

The semiconductor package 80 is similar to the semiconductor package 10 described with reference to FIG. 1A, except that the semiconductor package 80 includes a UV absorption substance 800 for filling up gaps around the device dies TD, rather than using a combination of the gap fill dielectric 132 and the dummy dies 134. As shown in FIG. 8A, the UV absorption substance 800 laterally surrounds each of the device dies TD, and is in contact with the insulating layer 112 at the bonding side of the device wafer BW as well as the bonding film 128 lying below. As shown in FIG. 8B, the paths P of the laser grooving and the mechanical sawing overlap the UV absorption substance 800.

If the UV light beams LS accidentally cut through the device wafer BW during the laser grooving, the UV absorption substance 800 would be exposed to the UV light beams LS. Since the UV absorption substance 800 can absorb UV lights, the UV light beams LS can be prevented from penetrating through the UV absorption substance 800 to reach the bonding film 128. Therefore, the bonding film 128 can be prevented from being damaged by the UV light beams LS, thus formation of cracks around the device dies TD due to damages of the bonding film 128 can be effectively avoided. Accordingly, reliability of the device dies TD would not be compromised.

In some embodiments, the UV absorption substance 800 is formed of a polymer material capable of absorbing UV lights. As examples, the UV absorption substance 800 may be formed of molding compound (e.g., epoxy), polyimide, benzocyclobutene (BCB) or the like. In alternative embodiments, the UV absorption substance 800 is formed of a polymer material added with UV absorbers, such as benzophenones, benzotriazoles, triazines, the like or combinations thereof.

In regarding manufacturing, process for forming the semiconductor package 80 is similar to the process described with reference to FIG. 2 and FIG. 3A to FIG. 3G, except for a few differences. Specifically, placing the dummy dies 134 and forming the gap fill dielectric 132 are replaced by forming the UV absorption substance 800 around the device dies TD, for forming the semiconductor package 80. Since the device dies TD are laterally encapsulated by the UV absorption substance 800, the bonding film 128 deposited after formation of the UV absorption substance 800 may cover the back sides of the device dies TD and the UV absorption substance 800.

FIG. 8C is a schematic cross-sectional view illustrating a semiconductor package 80a singulated from the semiconductor package 80, according to some embodiments of the present disclosure.

After performing the laser grooving and the mechanical sawing along the paths P shown in FIG. 8B, structures including the semiconductor package 80a are singulated from the semiconductor package 80. Since the laser grooving and the mechanical sawing cut through the UV absorption substance 800, the UV absorption substance 800 is exposed at sidewalls of the singulated semiconductor packages. According to some embodiments, for each of the singulated semiconductor packages (e.g., the semiconductor package 80), sidewalls of the UV absorption substance 800 are substantially coplanar with sidewalls of the singulated device wafer BW (i.e., the second device die), as well as sidewalls of the underlying bonding films 128, 130 and the support substrate 126.

As above, the present disclosure provides a semiconductor package and a manufacturing process for forming the semiconductor package. Particularly, the semiconductor package is formed with a three-dimensional design, and has multiple tiers stacked along a vertical direction. Due to the multilevel structure of the semiconductor package, singulation of the semiconductor package requires a laser grooving operation and a following mechanical sawing. The laser grooving may accidentally cut through a top tier of the semiconductor package, and a lower tier of the semiconductor package would be exposed to UV lights used for the laser grooving. Specifically, the lower tier of the semiconductor package includes a device die and a gap fill dielectric laterally surrounding the device die and penetrable to the UV lights. To prevent the UV lights from damaging material layer under the gap fill dielectric, dummy dies are placed in the gap fill dielectric and arranged along paths of the laser grooving. Since the dummy dies are capable of absorbing the UV lights, the material layer lying below can be prevented from exposing to and being damaged by the UV lights. As a result, formation of cracks in the gap fill dielectric due to damage of the underlying material layer can be effectively avoided, and reliability of the device die can be promised. As another alternative, air gaps are formed in the gap fill dielectric and arranged along the paths of the laser grooving. In this way, the underlying material layer would be exposed to and probably damaged by the UV lights. Nonetheless, since exposed portions of the material layer are lying under the air gaps but covered by the gap fill dielectric, formation of crack in the gap fill dielectric due to exposure of the material layer can be prevented. In further embodiments, the gap fill dielectric is entirely omitted, or replaced by a UV absorption substance. In these embodiments, cracks can also be prevented from forming around the device die, and reliability of the device die can be ensured.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In an aspect of the present disclosure, a semiconductor package is provided. The semiconductor package comprises: a first device die; a second device die, stacked on and bonded to the first device die; and a gap fill dielectric, laterally surrounding the second device die, and locally recessed toward the second device die with respect to the first device die, such that lateral recesses are defined at outer sidewalls of the gap fill dielectric.

In another aspect of the present disclosure, a semiconductor package is provided. The semiconductor package comprises a first device die; a second device die, stacked on and bonded to the first device die; dummy dies, attached to the first device die and arranged around the second device die; and a gap fill dielectric, laterally surrounding the second device die, and filled in between the dummy dies and the second device die, wherein the dummy dies and the gap fill dielectric are both exposed at sidewalls of the semiconductor package.

In yet another aspect of the present disclosure, a method for forming a semiconductor package is provided. The method comprises: providing a device substrate; separately placing a plurality of device dies onto the device substrate and bonding the device dies to the device substrate; attaching dummy dies onto the device substrate, wherein each of the device dies is laterally surrounded by a group of the dummy dies; forming a gap fill dielectric on the device substrate, to laterally encapsulate each of the device dies and each of the dummy dies; performing a singulation operation to cut through the dummy dies, the gap fill dielectric and the device substrate, for forming singulated package structures, wherein the dummy dies and the gap fill dielectric are both exposed at sidewalls of the singulated package structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first device die;
a second device die, stacked on and bonded to the first device die; and
a gap fill dielectric, laterally surrounding the second device die, and locally recessed toward the second device die with respect to the first device die, such that lateral recesses are defined at outer sidewalls of the gap fill dielectric.

2. The semiconductor package according to claim 1, wherein the lateral recesses are arranged along multiple sides of the second device die.

3. The semiconductor package according to claim 1, wherein each of the lateral recesses extends along a single side of the second device die.

4. The semiconductor package according to claim 1, wherein the lateral recesses are arranged in separated groups, the lateral recesses in each group are separated from one another, and arranged along a single side of the second device die.

5. The semiconductor package according to claim 1, wherein the lateral recesses are respectively arranged at a corner of the second device die.

6. The semiconductor package according to claim 1, wherein the outer sidewalls of the gap fill dielectric are in part substantially coplanar with sidewalls of the first device die.

7. The semiconductor package according to claim 1, further comprising:
a support substrate, stacked on and attached to the second device die and the gap fill dielectric, wherein the gap fill dielectric is locally recessed toward the second device die with respect to the first device die and the support substrate.

8. The semiconductor package according to claim 7, wherein sidewalls of the support substrate are substantially coplanar with sidewalls of the first device die.

9. The semiconductor package according to claim 7, wherein the support substrate is attached to the second device die and the gap fill dielectric through at least one bonding film.

10. The semiconductor package according to claim 9, wherein sidewalls of the at least one bonding film are substantially coplanar with sidewalls of the support substrate and sidewalls of the first device die.

11. The semiconductor package according to claim 1,
wherein a first insulating layer and first bonding pads are formed along a bonding side of the first device die,
wherein a second insulating layer and second bonding pads are formed along a bonding side of the second device die,
wherein the first insulating layer is bonded to the second insulating layer, and the first bonding pads are bonded to the second bonding pads, respectively.

12. The semiconductor package according to claim 11, wherein the first insulating layer and the first bonding pads are disposed on a back side of a semiconductor substrate of the first device die, and the first device die further comprises through substrate vias penetrating through the semiconductor substrate.

13. A semiconductor package, comprising:
a first device die;
a second device die, stacked on and bonded to the first device die;
dummy dies, attached to the first device die and arranged around the second device die; and
a gap fill dielectric, laterally surrounding the second device die, and filled in between the dummy dies and the second device die, wherein the dummy dies and the gap fill dielectric are both exposed at sidewalls of the semiconductor package.

14. The semiconductor package according to claim 13, wherein outer sidewalls of the dummy dies are substantially coplanar with sidewalls of the first device die.

15. The semiconductor package according to claim 13, wherein the outer sidewalls of the gap fill dielectric are in part substantially coplanar with outer sidewalls of the dummy dies.

16. The semiconductor package according to claim 13, wherein the dummy dies are in lateral contact with the second device die through the gap fill dielectric.

17. The semiconductor package according to claim 13, wherein the dummy dies are respectively attached to the first device die via a bonding layer.

18. The semiconductor package according to claim 13, wherein the dummy dies respectively comprise a silicon substrate without electrical components formed thereon.

19. A method for forming a semiconductor package, comprising:
providing a device substrate;
separately placing a plurality of device dies onto the device substrate and bonding the device dies to the device substrate;
attaching dummy dies onto the device substrate, wherein each of the device dies is laterally surrounded by a group of the dummy dies;
forming a gap fill dielectric on the device substrate, to laterally encapsulate each of the device dies and each of the dummy dies;
performing a singulation operation to cut through the dummy dies, the gap fill dielectric and the device substrate, for forming singulated package structures, wherein the dummy dies and the gap fill dielectric are both exposed at sidewalls of the singulated package structures.

20. The method for forming the semiconductor package according to claim 19, further comprising:
attaching a support substrate to the device dies, the dummy dies and the gap fill dielectric before performing the singulation operation, wherein the support substrate is also cut through during the singulation operation.
